(19) United States
(12) Patent Application Publication
(10) Pub. No.: US 2002/0013098 A1
(43) Pub. Date: Jan. 31, 2002

(54) DISPLAY DEVICE HAVING A CONDUCTOR PATTERN FOR CONNECTING PIXELS IN AN ELECTRICALLY CONDUCTING MANNER

(76) Inventors: Jozeph W. Triepels, Heerlen (NL); Roel H. L. Kusters, Heerlen (NL); Fransiscus G. C. Verweg, Heerlen (NL); Henri S. A. Handels, Heerlen (NL); Marcel S. B. Bachus, Heerlen (NL); Johannes W. J. M. Scheuermann, Heerlen (NL)

Correspondence Address: C/O U.S. PHILIPS CORPORATION, INTELLECTUAL PROPERTY DEPARTMENT, 580 WHITE PLAINS ROAD, TARRYTOWN, NY, 10591, US

(21) Appl. No.: 09/519,547

(22) Filed: Mar. 6, 2000

(30) Foreign Application Priority Data
Mar. 9, 1999 (EP) 99200696.5

(51) Int. Cl. H01R 13/40

(52) U.S. Cl. 439/625

(57) ABSTRACT

Conductor tracks (8) on a board or substrate (9) are connected to conductor tracks (14) on a substrate of a display device (3) by gold-gold contacts. Especially if resistant interconnections (15) are used, very reliable pressure contacts are obtained. Display device

The invention relates to a display device comprising a first substrate having a conductor pattern for connecting pixels in an electrically conducting manner, parts of which are connected in an electrically conducting manner to connection tracks on a support. A conductor pattern may be understood to be both a pattern of exclusively column and row conductors and a more extensive pattern in which drive ICs are incorporated.

Display devices of this type, particularly liquid crystal display devices, are used very generally in, for example, measuring apparatus, but also in, for example, portable telephones. Moreover, electroluminescent display devices, based on (organic) LEDs find an increasingly wider application.

With the ever increasing miniaturization of electronics, it is possible to realize an ever increasing number of drive electronics on the substrate. However, there is also a tendency to manufacture the actual display panel (display section) as a standard component. If such a standard component is mounted in an apparatus, for example, by soldering on the support (for example, a printed circuit board or another type of substrate provided with conducting (connection) tracks), or by clamping, stringent requirements are imposed on the contacts (low resistance, mechanical stability, etc.). To this end, contact paste is often used between the conductor pattern and further contact elements, such as connectors in connector housings, contact pins, etc. In addition, notably the tolerances of connection tracks to be connected on the support may become very strict with respect to the associated parts of the conductor pattern.

It is, inter alia, an object of the invention to provide a display device of the type described above in which connection conductors on the surface area of the first substrate are connected in a reliable manner to connection tracks on the support.

To this end, the invention is characterized in that the conducting connection between at least a part of the conductor pattern and a connection track comprises a metal-metal contact, in which each metal of the metal-metal contact is chosen from the group of gold, silver and nickel. Since these metals are not attacked or are hardly attacked or oxidized, a pressure contact is sufficient in the final assembly.

The metal-metal contact is preferably a gold-gold contact.

A first embodiment of a display device according to the invention is characterized in that the conducting connection between at least a part of the conductor pattern and a connection track comprises a resilient conductor.

Since a satisfactorily conducting material (for example, gold) is chosen for the resilient conductor, the resistance of the contact between the conductor pattern and the connection track is negligible.

In this connection, a resilient conductor is understood to be any conductor in which, by compression of the conductor between two conducting faces, an electrically conducting contact between the two faces is obtained or maintained. Examples are so-called pogopins as described in, for example, U.S. Pat. No. 5,157,325 and JP-A-4-22077, but also the pins as described in U.S. Pat. No. 5,500,606 are possible. A possible conducting paste between the resilient conductor and the conductor track, which is cured by UV radiation, can now be dispensed with. This reduces the number of mounting steps (providing the paste, curing) for the end user (or the final assembly) where only mechanical handling is preferably performed.

A further embodiment of a display device according to the invention is characterized in that the conducting connection between the resilient conductor and the part of the conductor pattern comprises an anisotropically conducting foil.

This embodiment has the advantage that the foil can extend across the first substrate as far as, for example, the contacts of (drive) ICs. The conductance between the contact and the connection of the IC now takes place via the conductor of the foil (for example, copper tracks) so that a more low-ohmic connection is realized.

The invention is notably suitable for a display device in which the conductor pattern is present on the support-facing side of the first substrate.

The conductor pattern may be alternatively present on the other side of the substrate. Such a display device is characterized in that conductors associated with the conductor pattern extend as far as proximate to an edge of the first substrate, a conductor part associated with the electrically conducting connection between the connection track and the part of the conductor pattern enclosing the edge at the area of said edge.

The invention is applicable to display devices based on liquid crystal effects or other electro-optical effects, in which an electro-optical material is present between two substrates. Such an embodiment is characterized in that the display device comprises a second substrate and an electro-optical material between the two substrates, each being provided with picture electrodes which define pixels with the interpositioned electro-optical material, the first substrate being provided with the conductor pattern beyond the part of the first substrate located opposite the second substrate. The display device may also be based on an electroluminescent effect.

The resilient conductor may alternatively contact the support on the side remote from the first substrate. Such a display device is characterized in that at least one resilient conductor contacts a conductor pattern on the side of the support remote from the first substrate.

These and other aspects of the invention are apparent from and will be elucidated with reference to the embodiment(s) described hereinafter.

In the drawings:

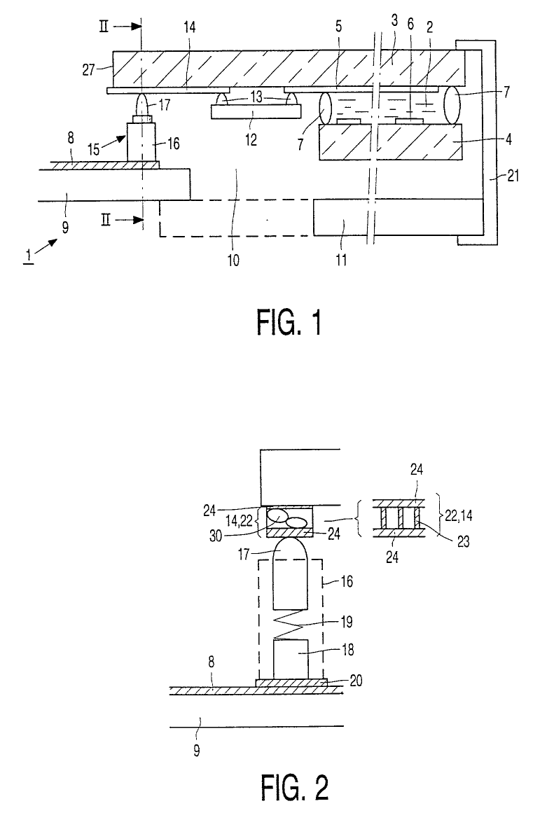

FIG. 1 is a diagrammatic cross-section of a part of a first embodiment of a display device according to the invention,

FIG. 2 is a diagrammatic cross-section taken on the line II-II in FIG. 1,

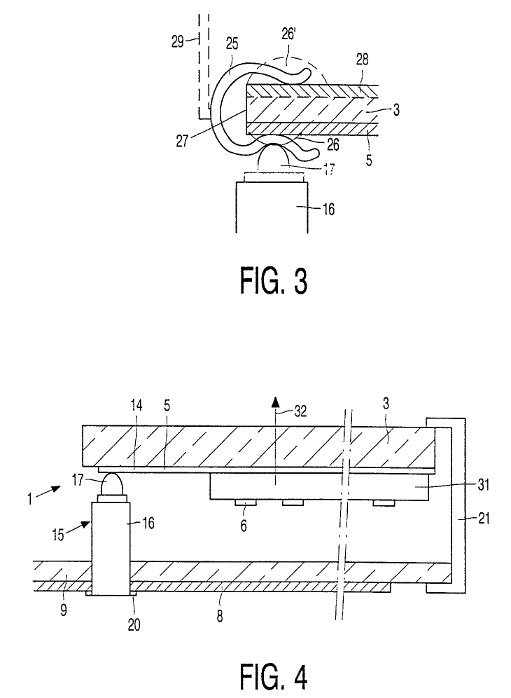

FIG. 3 shows a variant of the connection shown in FIG. 2, while

FIG. 4 is a diagrammatic cross-section of a part of a second embodiment of a display device according to the invention.

The Figures are diagrammatic and not drawn to scale; corresponding parts generally have the same reference numerals.

FIG. 1 is a diagrammatic cross-section of a part of a display device, in this embodiment a liquid crystal display device, comprising a liquid crystal cell 1 having, in this embodiment, a twisted nematic liquid crystal material 2 which is present between two transparent substrates 3, 4 of, for example, glass, provided with electrodes 5, 6. The device further comprises polarizers (not shown) whose direction of polarization is, for example, mutually perpendicularly crossed. The device also comprises orientation layers (not shown) which orient the liquid crystal material on the inner walls of the substrates, in this embodiment in such a way that the cell has a twist angle of 90 degrees. In this case, the liquid crystal material has a positive optical anisotropy and a positive dielectric anisotropy. If the electrodes 5, 6 are energized with an electric voltage, the molecules and hence the directors orient themselves to the field. The cell 1 is bounded by a cell wall or sealing edge 7.

The transparent electrodes 5, 6 of, for example, ITO (indium-tin oxide) which mutually cross each other perpendicularly in this embodiment and define pixels at the area of the crossings must be supplied with drive voltages. These may be applied externally, for example, via conducting tracks 8 on a support 9 such as a printed circuit board. In the device of FIG. 1, the support has an opening 10 in which, if necessary, an illumination source 11 may be arranged.

In the embodiment of FIG. 1, the electrodes 5 are supplied with drive voltages by means of a drive circuit (IC) 12 mounted on the first substrate 3. Contacting of the electrodes 5 (and also the electrodes 6 via methods which are conventional in the LCD technology) takes place via bumps 13. Other bumps 13 contact conductors 14 to be further described. Where in this application a “conductor pattern” on the substrate 3 is referred to, parts or the whole of conductors 14 are meant. In certain cases, the conductors 14 largely also consist of ITO, particularly when there are no ICs on the substrate 3. In other cases (in so-called active matrix LCDs) polysilicon tracks may be part of the conductor pattern.

As stated in the preamble, there is a great need of, for example, LCD screens (in this embodiment the assembly of the substrates 3, 4 with the liquid in between and the conductor tracks and drive circuits arranged on the substrates) to be supplied as one assembly, whereafter the final assembly takes place without any cumbersome steps. However, this should not be at the expense of a satisfactory contact which is necessary between the tracks 8 and the conductor pattern 5, 14.

According to the invention, the display device therefore comprises a metal-metal contact, in this embodiment a gold-gold contact, between a conductor track 14 and a connection pin, in this embodiment a resilient pin 15 (see also FIG. 2). Other suitable metals are silver and nickel.

In the embodiment of FIG. 2, use is made of an anisotropic conductor 14 for the conductor 14, in this embodiment a polyimide copper foil 22, with electrically conducting copper particles 30 which, upon compression, establish an electrically conducting connection between the two surface layers which are gold-plated on their surface (gold layers 24).

The conductor 14 may consist of a small metallized plate. Preferably, the material of this plate is also gold so that a gold-gold contact between the pin part 17 and the conductor 14 is obtained. Such contacts are very low-ohmic and very reliable, so that final assembly of the display device can take place without extra precautions. On the other hand, a different type of anisotropic conductor with conducting copper tracks 23 transverse to the foil may be used for the conductor 14, which copper tracks extend in one direction, in this embodiment in the direction of the pins 15 to the IC 12. In this embodiment, the foils are gold-plated on both sides throughout their surface so as to prevent oxidation of the copper (gold layers 24).

Since the foils 22 are gold-plated at the location of the contact with the pin 15, the contact between the conductor 13 and the pin 15 has all of the above-mentioned advantages of the gold-gold contact. In this embodiment, the foils are gold-plated on both sides throughout their surface (gold layers 24) so that an extra satisfactory conduction of the conductors 14 is ensured.

A cylindrical housing 16 of the pin 15 incorporates two conducting pin parts 17, 18, in this embodiment of gold, which are interconnected in an electrically conducting and mechanical manner by a resilient part 19 (within the housing 16). In this embodiment, the pin 15 has an electrically conducting surface 20 with the pin part 18 but this is not strictly necessary. The pin part 18 may also have a round or pointed end on the side facing the support 9.

In the final assembly, the assembly of the substrates 3, 4 with the liquid in between and the conductor tracks and drive circuits on the substrates is mounted together with the backlight 11, for example, by a clamping connection 21 or by molding in a plastic envelope under simultaneous pressure.

Since the resilient part 19 is compressed and subsequently the pressure on this resilient part is maintained by the clamp 21 or in a different way, the conductor 8 on the support 9 is connected in an electrically conducting manner to the conductor 14 on the substrate 3 via a pressure contact. Instead of this pogopin, other electrically conducting contact means may be used, such as anisotropically conducting foil contacts.

FIG. 3 shows a variant in which an ITO conductor 5 extends as far as (or proximate to) the edge 27 of the substrate 3. An electrically conducting U-shaped part 25, which is bent around the edge and secured by means of UV glue 26, is now provided between the pin part 17 and the conductor 14. This results in a mechanically tighter construction. The conducting U-shaped part 25 (of a suitable metal such as gold, silver or nickel) may be provided by clamping, for example, by making use of suitable “glued-on pins” which, beyond the conductor part 15, comprise a pin part 29 used for further contacting in other applications. In this embodiment, the parts 29 are cut off after mounting.

Viewed transversely to the drawing, the device of FIG. 3 may also comprise a plurality of such conductor parts 25 which are accommodated in a connector housing. The conductor parts are, for example, punched from a suitable material having a satisfactory electrical conductance such as silver or locally gold-plated phosphor bronze and then molded in a synthetic material housing. The shape and dimension of the conductor parts and the connector housing are preferably chosen to be such that a clamping connection is obtained after the connector housing has been slid around the edge of the substrate 3. Consequently, a satisfactorily electrically conducting contact is obtained between the conductor track (the conductor) 14 and the conductor parts 25. To avoid contact resistances, a conducting paste may be provided, if necessary, at the contact areas between conductor tracks 14 and the conductor parts 25. The electric contact between the conductor part 14 and the conductor 8 may be realized, for example, by a mechanical clamping connection.

In the embodiments hitherto described, the conductor pattern 14 is present on the side of the substrate 3 facing the support 9. The layer 28 denoted by means of broken lines shows that a conductor pattern 28 may be alternatively contacted on the other side of the substrate when using the configuration shown in FIG. 3. In FIG. 1, the conductor 14 is shown as far as beyond the edge 27 of the substrate 3 so as to make clear that also a foil as described with reference to FIG. 2 can be bent around the substrate in order to enhance the mechanical rigidity in a similar manner or, if necessary, to contact conductors on the other surface of the substrate 3.

FIG. 4 shows a variant in which the display device on the substrate 3 has a layer 31 of an electroluminescent material in which poly-LED pixels are defined, for example, by means of the electrodes 5, 6. In this embodiment, the electrode 5 is connected in an electrically conducting manner to the pin part 17 via a small gold-plated plate 14 (or an anisotropic conductor as described above). The other contact of the resilient pin is now constituted by a conducting part 20 contacting the conductor 8 via soldering or by way of the resilient force. The pin 15 is adapted in such a way that the conductor 8 is present on the other side of the support remote from the pixels, but the construction of FIG. 1 is alternatively possible. The arrow 32 represents the light emitted by the poly-LEDs. Since no backlight is necessary in this case, the support 8 may extend under the layer 30 of electroluminescent material where it may comprise, for example, drive electronics (on one side or both sides of the support 9).

The invention is of course not limited to the embodiments shown, but many variations are possible within the scope of the invention. For example, instead of liquid crystal materials, other electro-optical materials such as electrophoretic or electrochromic materials may be used. The resilient part 19 may also be dispensed with in the resilient pin 15, provided that the distance between the pin parts 17, 18 is sufficiently small to ensure electric contact when the separate parts of the display device are being secured (molded, clicked tight).

In summary, the invention relates to connecting conductor tracks to a support and conductor tracks to a substrate of a display device via resilient conductors. Notably when using gold-gold contacts, very reliable pressure contacts are obtained.

The invention relates to each and every novel characteristic feature and each and every combination of characteristic features.

1. A display device comprising a first substrate having a conductor pattern for connecting pixels in an electrically conducting manner, parts of which are connected in an electrically conducting manner to connection tracks on a support, characterized in that the conducting connection between at least a part of the conductor pattern and a connection track comprises a metal-metal contact, in which each metal of the metal-metal contact is chosen from the group of gold, silver and nickel.

2. A display device as claimed in claim 1, characterized in that the metal-metal contact comprises a gold-gold contact.

3. A display device as claimed in claim 1, characterized in that the metal-metal contact is present at the area of the first substrate.

4. A display device as claimed in claim 1, characterized in that the conducting connection between at least a part of the conductor pattern and a connection track comprises a resilient conductor.

5. A display device as claimed in claim 4, characterized in that the conducting connection between the resilient conductor and the part of the conductor pattern comprises an anisotropically conducting foil.

6. A display device as claimed in claim 1, characterized in that the conductor pattern is present on the support-facing side of the first substrate.

7. A display device as claimed in claim 1, characterized in that conductors associated with the conductor pattern extend as far as proximate to an edge of the first substrate, a conductor part associated with the electrically conducting connection between the connection track and the part of the conductor pattern enclosing the edge at the area of said edge.

8. A display device as claimed in claim 1, characterized in that the display device comprises a second substrate and an electro-optical material between the two substrates, each being provided with picture electrodes which define pixels with the interpositioned electro-optical material, the first substrate being provided with the conductor pattern beyond the part of the first substrate located opposite the second substrate.

9. A display device as claimed in claim 1, characterized in that the display device comprises an electroluminescent material.

10. A display device as claimed in claim 1, characterized in that at least a part of the conductor pattern is connected in an electrically conducting manner to a connection track on the side of the support remote from the first substrate.
